(19) United States
(12) Patent Application Publication
(10) Pub. No.: US 2024/0035195 A1
(43) Pub. Date: Feb. 1, 2024

(54) METHODS, SYSTEMS, AND APPARATUS FOR FORMING LAYERS HAVING SINGLE CRYSTALLINE STRUCTURES

(71) Applicant: Applied Materials, Inc., Santa Clara, CA (US)

(72) Inventors: Qinghua ZHAO, Belmont, CA (US); Rui CHENG, Santa Clara, CA (US); Dimitrios PAVLOPOULOS, Glendale, CA (US); Karthik JANAKIRAMAN, San Jose, CA (US)

(21) Appl. No.: 18/226,007

(22) Filed: Jul. 25, 2023

Related U.S. Application Data
(60) Provisional application No. 63/393,681, filed on Jul. 29, 2022.

(51) Int. Cl. C30B 25/16; H01L 21/02; H01J 37/32; C30B 29/06; C30B 29/52; C30B 25/10; C23C 16/06; C23C 16/24; C23C 16/46; C23C 16/507; C23C 16/52

(52) U.S. Cl. CPC C30B 25/165; H01L 21/02532; H01L 21/02598; H01L 21/0262; H01J 37/32816; H01J 37/32724; H01J 37/32449; C30B 29/06; C30B 29/52; C30B 25/10; C23C 16/06; C23C 16/24; C23C 16/46; C23C 16/507; C23C 16/52; H01J 2237/332; H01J 2237/2001; H01J 2237/182

(57) ABSTRACT

Embodiments of the present disclosure generally relate to methods, systems, and apparatus for forming layers having single crystalline structures. In one implementation, a method of processing substrates includes positioning a substrate in a processing volume of a chamber, and heating the substrate to a substrate temperature that is 800 degrees Celsius or less. The method includes maintaining the processing volume at a pressure within a range of 1.0 Torr to 8.0 Torr, and flowing one or more silicon-containing gases and one or more diluent gases into the processing volume. The method includes reacting the one or more silicon-containing gases to form one or more reactants, and depositing the one or more reactants onto an exposed surface of the substrate to form one or more silicon-containing layers on the exposed surface. The one or more silicon-containing layers each having a single crystalline structure.

### CROSS-REFERENCE TO RELATED APPLICATION

This application claims the benefit of U.S. provisional patent application Ser. No. 63/393,681, filed Jul. 29, 2022, which is herein incorporated by reference in its entirety.

### BACKGROUND

### Field

Embodiments of the present disclosure generally relate to methods, systems, and apparatus for forming layers having single crystalline structures. In one or more embodiments, the layers include one or more silicon (Si) layers and one or more silicon-germanium (SiGe) layers.

### Description of the Related Art

Performance capabilities can call for certain semiconductor properties, such as in the context of 3D DRAM applications. However, attempts to meet the properties can involve several hindrances. For example, processing chambers can be expensive, complex, and time-consuming. As an example, chambers may use a large amount of power during processing (such as for relatively high temperatures), and can involve components that are complex and expensive. As another example, processing chambers can involve a low throughput. Moreover, operations can be limited in modularity for single-sided and double-sided deposition applications.

Therefore, there is a need for improved methods, systems, and apparatus that facilitate beneficial substrate properties while facilitating one or more of reduced costs, reduced complexity, reduced operation times, enhanced modularity, and enhanced throughput.

### SUMMARY

Embodiments of the present disclosure generally relate to methods, systems, and apparatus for forming layers having single crystalline structures. In one or more embodiments, the layers include one or more silicon (Si) layers and one or more silicon-germanium (SiGe) layers.

In one or more embodiments, a method of processing substrates includes positioning a substrate in a processing volume of a chamber, and heating the substrate to a substrate temperature that is 800 degrees Celsius or less. The method includes maintaining the processing volume at a pressure within a range of 1.0 Torr to 8.0 Torr, and flowing one or more silicon-containing gases and one or more diluent gases into the processing volume. The method includes reacting the one or more silicon-containing gases to form one or more reactants, and depositing the one or more reactants onto an exposed surface of the substrate to form one or more silicon-containing layers on the exposed surface. The one or more silicon-containing layers each having a single crystalline structure.

In one or more embodiments, a non-transitory computer readable medium includes instructions that, when executed, cause a plurality of operations to be conducted. The plurality of operations includes positioning a substrate in a processing volume of a chamber, and heating the substrate to a substrate temperature that is 800 degrees Celsius or less. The plurality of operations includes maintaining the processing volume at a pressure within a range of 1.0 Torr to 8.0 Torr, and flowing one or more silicon-containing gases and one or more diluent gases into the processing volume. The plurality of operations include reacting the one or more silicon-containing gases to form one or more reactants, and depositing the one or more reactants onto an exposed surface of the substrate to form one or more silicon-containing layers on the exposed surface. The one or more silicon-containing layers each have a single crystalline structure.

In one or more embodiments, a system for processing substrates includes a chamber. The chamber includes one or more sidewalls that at least partially define a processing volume, a substrate support positioned in the processing volume, one or more heating elements embedded in the substrate support, and a lid defining a ceiling of the processing volume. The lid includes one or more gas passages. The chamber includes a radio-frequency (RF) power source electrically coupled to the chamber, and a controller that includes instructions that, when executed by a processor, cause a plurality of operations to be conducted. The plurality of operations include positioning a substrate in the processing volume of the chamber, and heating the substrate to a substrate temperature that is within a range of 545 degrees Celsius to 555 degree Celsius. The plurality of operations include forming a plasma in the processing volume, and activating the exposed surface of the substrate using the plasma. The plurality of operations include extinguishing the plasma, exhausting the processing volume, maintaining the substrate at the substrate temperature, and maintaining the processing volume at a pressure within a range of 5.8 Torr to 6.2 Torr. The plurality of operations include flowing one or more silicon-containing gases and one or more diluent gases into the processing volume through the ceiling of the processing volume. The plurality of operations include reacting the one or more silicon-containing gases to form one or more reactants, and depositing the one or more reactants onto an exposed surface of the substrate to form one or more silicon-containing layers on the exposed surface. The one or more silicon-containing layers each have a single crystalline structure, an abruptness that is less than 1.0, and a surface roughness that is less than 0.2 nm.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic top-view diagram of a system for processing substrates, according to one or more embodiments.

FIG. 2 is a schematic cross-sectional view of a processing chamber, according to one or more embodiments.

FIG. 3 is a schematic cross-sectional view of a processing chamber, according to one or more embodiments.

FIG. 4 is a schematic block diagram view of a method of processing substrates, according to one or more embodiments.

FIG. 5 is a schematic cross-sectional view of a substrate and a plurality of layers formed on the substrate, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to methods, systems, and apparatus for forming layers having single crystalline structures. In one or more embodiments, the layers include one or more silicon (Si) layers and one or more silicon-germanium (SiGe) layers.

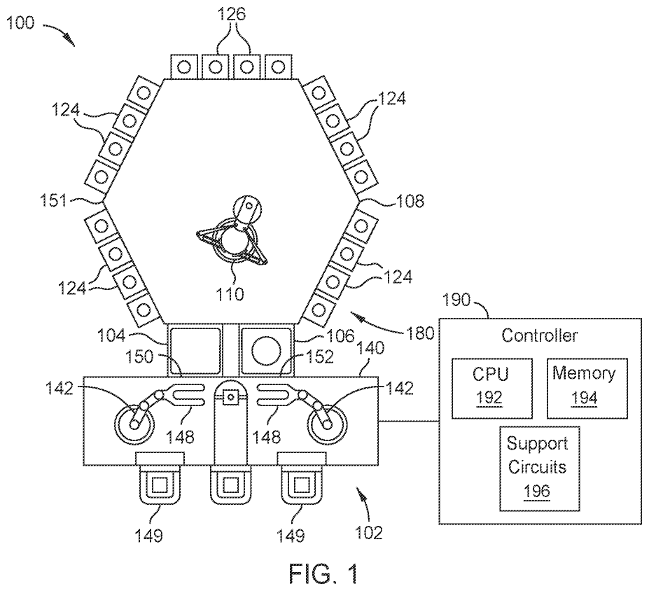

FIG. 1 is a schematic top-view diagram of a system 100 for processing substrates, according to one or more embodiments. The system 100 includes a cluster tool 180. The cluster tool 180 includes a factory interface 102, one or more transfer chambers 108 (one is shown) with a transfer robot 110 disposed therein. The cluster tool 180 includes one or more first chambers 124 (sixteen are shown) and one or more second chambers 126 (four are shown) mounted to a mainframe 151 of the single cluster tool 180. The one or more first chambers 124 are deposition chambers, such as chemical vapor deposition (CVD) chambers. The one or more second chambers 126 are cleaning chambers. One or more of the second chambers 126 are pre-clean chambers (where cleaning occurs prior to deposition in the first chambers 124), and one or more of the second chambers 126 are post-clean chambers (where cleaning occurs after deposition in the first chambers 124). The chambers 124, 126 can all run simultaneously to process substrates. The present disclosure contemplates that the first chambers 124 and the second chambers 126 may be on different mainframes such that there is a vacuum break during transfer between the first chambers 124 and the second chambers 126. The present disclosure contemplates that a vacuum break may also occur within the single cluster tool 180 during transfer of the substrates between chambers. In one or more embodiments, the vacuum break lasts for a duration within a range of 4.0 minutes to 5.0 minutes, or less than 4.0 minutes.

In one or more embodiments, substrates in the system 100 can be processed in and transferred between the various chambers without being exposed to an ambient environment exterior to the cluster tool 180. In one or more embodiments, the system 100 provides an integrated cluster tool 180 for conducting processing operations on substrates.

In the implementation shown in FIG. 1, the factory interface 102 includes a docking station 140 and factory interface robots 142 to facilitate transfer of substrates. The docking station 140 is configured to accept one or more front opening unified pods (FOUPs) 149. In one or more embodiments, each factory interface robot 142 includes a blade 148 disposed on one end of the respective factory interface robot 142 configured to transfer substrates from the factory interface 102 to the load lock chambers 104, 106.

The load lock chambers 104, 106 have respective doors 150, 152 interfacing with the factory interface 102 and respective doors 154, 156 interfacing with the transfer chamber 108. The first and second second chambers 124, 126 have respective doors interfacing with the transfer chamber 108.

The doors can include, for example, slit openings with slit valves for passing substrates therethrough by the transfer robot 110 and for providing a seal between respective chambers to prevent a gas from passing between the respective chambers. A door can be open for transferring a substrate therethrough, and otherwise closed.

The load lock chambers 104, 106, the transfer chamber 108, the first chambers 124, and the second chambers 126 may be fluidly coupled to a gas and pressure control system. The gas and pressure control system can include one or more gas pumps (e.g., turbo pumps, cryo-pumps, roughing pumps, vacuum pumps, etc.), gas sources, various valves, and conduits fluidly coupled to the various chambers.

The system 100 includes a controller 190 configured to control the system 100 or components thereof. For example, the controller 190 may control the operation of the system 100 using a direct control of the chambers 104, 106, 108, 124, 126 of the system 100 or by controlling other computers or controllers (such as sub-controllers) associated with the chambers 104, 106, 108, 124, 126. In one or more embodiments, the controller 190 is communicatively coupled to dedicated controllers, and the controller 190 functions as a central controller. The controller 190 is configured to control the gas and pressure control system. In operation, the controller 190 enables data collection and feedback from the respective chambers and the gas and pressure control system to coordinate and control performance of the system 100.

The controller 190 generally includes a central processing unit (CPU) 192, a memory 194, and support circuits 196. The CPU 192 may be one of any form of a general purpose processor that can be used in an industrial setting for controlling various substrate processing chambers and equipment, and sub-processors thereon or therein. The memory 194, or non-transitory computer readable medium, is accessible by the CPU 192 and may be one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 196 are coupled to the CPU 192 for supporting the CPU 192 and may include cache, clock circuits, input/output circuitry and/or subsystems, power supplies, and the like.

The various methods (such as the method 400) and operations disclosed herein may generally be implemented under the control of the CPU 192 by the CPU 192 executing computer instruction code stored in the memory 194 (or in memory of a particular processing chamber) as, e.g., a software routine. When the computer instruction code (e.g., instructions) is executed by the CPU 192, the CPU 192 controls the chambers to conduct processes in accordance with the various methods and operations described herein. In one or more embodiments, the memory 194 includes instructions stored therein that, when executed, cause the methods (such as the method 400) and operations (such as the operations 401, 402, 404, 405, 406, 408, 410, 412, 414, 416) described herein to be conducted using the various apparatus and components (such as the chambers 124, 126) described herein. In one or more embodiments, the controller 190 is configured to use one or more machine learning algorithms and/or artificial intelligence algorithms to optimize one or more processing parameters (such as substrate temperature and/or pressure used in the chambers 124 and/or 126). The one or more machine learning algorithms and/or artificial intelligence algorithms can account for data collected from the system 100 (such as from the chambers 124 and/or 126) during processing of substrates to optimize the one or more processing parameters.

The various operations described herein (such as the operations 401, 402, 404, 405, 406, 408, 410, 412, 414, 416 of the method 400) can be conducted automatically using the controller 390, or can be conducted automatically or manually with certain operations conducted by a user.

Other processing systems in other configurations are contemplated. For example, more or fewer processing chambers (e.g., six first chambers 124) may be coupled to a transfer apparatus. In the implementation shown in FIG. 1, the transfer apparatus includes the transfer chamber 108. In other implementations, more or fewer transfer chambers (e.g., two transfer chambers) may be implemented as a transfer apparatus in a system for processing substrates.

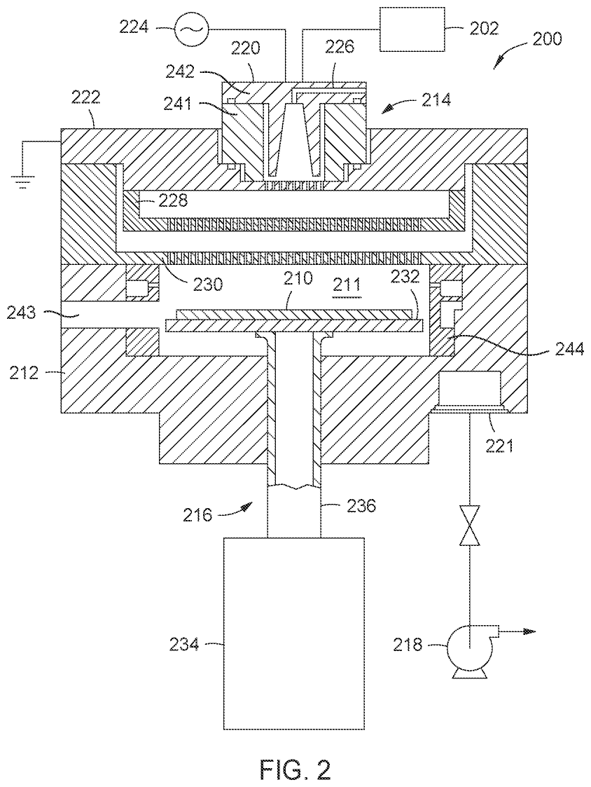

FIG. 2 is a schematic cross-sectional view of a processing chamber 200, according to one or more embodiments. The processing chamber 200 is a cleaning chamber, such as a pre-clean chamber. The processing chamber 200 may be used as one or more of the second chambers 126 shown in FIG. 1. The processing chamber 200 can be configured to conduct a thermal or plasma-based oxidation process and/or a plasma assisted dry etch process. The processing chamber 200 includes a chamber body 212, a lid assembly 214, and a support assembly 216. The lid assembly 214 is disposed at an upper end of the chamber body 212, and the support assembly 216 is at least partially disposed within the chamber body 212. A vacuum system can be used to remove gases from the processing chamber 200. The vacuum system includes a vacuum pump 218 coupled to a vacuum port 221 disposed in the chamber body 212. The vacuum system can be part of the gas and pressure control system of FIG. 1.

The lid assembly 214 includes at least two stacked components 222, 241, 242 (three are shown) configured to form a plasma volume or cavity therebetween. A first electrode 220 is disposed vertically above a second electrode 222 confining a plasma volume. The first electrode 220 is connected to a power source 224, such as a radio frequency (RF) power supply, and the second electrode 222 is connected to ground or a source return, forming a capacitance between the first electrode 220 and the second electrode 222. The lid assembly 214 includes one or more gas inlets 226 for providing a cleaning gas to a substrate surface through a blocker plate 228 and a gas distribution plate 230. The cleaning gas may be an etchant or ionized active radical, such as ionized fluorine, chlorine, or ammonia; and/or an oxidizing agent, such as ozone. The processing chamber 200 includes a controller 202 for controlling processes within the processing chamber 200. The controller 202 can be part of (e.g., integrated with) or in communication with the controller 190 shown in FIG. 1.

The support assembly 216 may include a substrate support 232 to support a substrate 210 thereon during processing. The substrate support 232 may be coupled to an actuator 234 by a shaft 236, which extends through a centrally-located opening formed in a bottom surface of the chamber body 212. The actuator 234 may be flexibly sealed to the chamber body 212 by bellows (not shown) that prevent vacuum leakage from around the shaft 236. The actuator 234 allows the substrate support 232 to be moved vertically within the chamber body 212 between a process position and a lower, transfer position. The transfer position is slightly below an opening 243 of a slit valve formed in a sidewall of the chamber body 212. A pumping ring 244 (which can include one or more pumping liners) is disposed in a first processing volume 211 of the processing chamber 200 to facilitate exhausting gases from the first processing volume 211.

The substrate support 232 has a flat, or a substantially flat, surface for supporting a substrate 210 to be processed thereon. The substrate support 232 may be moved vertically within the chamber body 212 by actuator 234 coupled thereto by shaft 236. In operation, the substrate support 232 may be elevated to a position in close proximity to the lid assembly 214 to control the temperature of the substrate 210 being processed. As such, the substrate 210 may be heated via radiation emitted or convection from the gas distribution plate 230.

The processing chamber 200 is configured to conduct a cleaning operation on the substrate 210 to remove, for example, a native oxide from the substrate 210. The native oxide can include SiO₂. The cleaning operation is conducted while maintaining the first processing volume 211 of the processing chamber 200 at a clean pressure and a clean temperature. The clean temperature is 1,000 degrees Celsius or less, such as 800 degrees Celsius or less. In one or more embodiments, the clean temperature is within a range of 15 degrees Celsius to 130 degrees Celsius, such as 20 degrees Celsius to 100 degrees Celsius. In one or more embodiments, the clean temperature is within a range of 0 degrees Celsius to 50 degrees Celsius, such as 20 degrees Celsius to 40 degrees Celsius. The clean pressure is less than 700 Torr, such as 600 Torr or less. In one or more embodiments, the clean pressure is within a range of 5 Torr to 600 Torr. In one or more embodiments, the clean pressure is within a range of 30 Torr to 80 Torr. In one or more embodiments, the clean pressure is 5 Torr, 300 Torr, or 600 Torr.

During the cleaning operation, the substrate 210 can be exposed to a plasma that is generated. The plasma includes one or more of NH₃, and/or NF₃. The plasma can also include one or more inert gases such as one or more of helium (He), nitrogen (N₂), and/or argon (Ar). The plasma can be a capacitively coupled plasma or an inductively coupled plasma. The plasma can be supplied from a remote plasma source, and the plasma can be introduced into a processing chamber through a gas distribution plate, such as a showerhead. NH₃ is directly injected into the chamber via a separate gas inlet. The cleaning operation can include exposing the substrate 210 to a thermal combination of anhydrous HF and NH₃, exposing the substrate 210 to aqueous HF, a dry etch operation (such as a remote plasma assisted dry etch operation), and/or a silicon-etching operation (e.g., ICP H₂/Cl₂ silicon etching). The dry etch operation can include exposure of the substrate 210 to NF₃ and NH₃ plasma by-products.

The cleaning operation can include a wet clean operation. The substrate 210 may be cleaned using a wet cleaning operation in which the substrate 210 is exposed to a cleaning solution, such as a HF-last type cleaning solution, ozonated water cleaning solution, hydrofluoric acid (HF) and hydrogen peroxide (H₂O₂) solution, and/or other suitable cleaning solution. The cleaning solution may be heated.

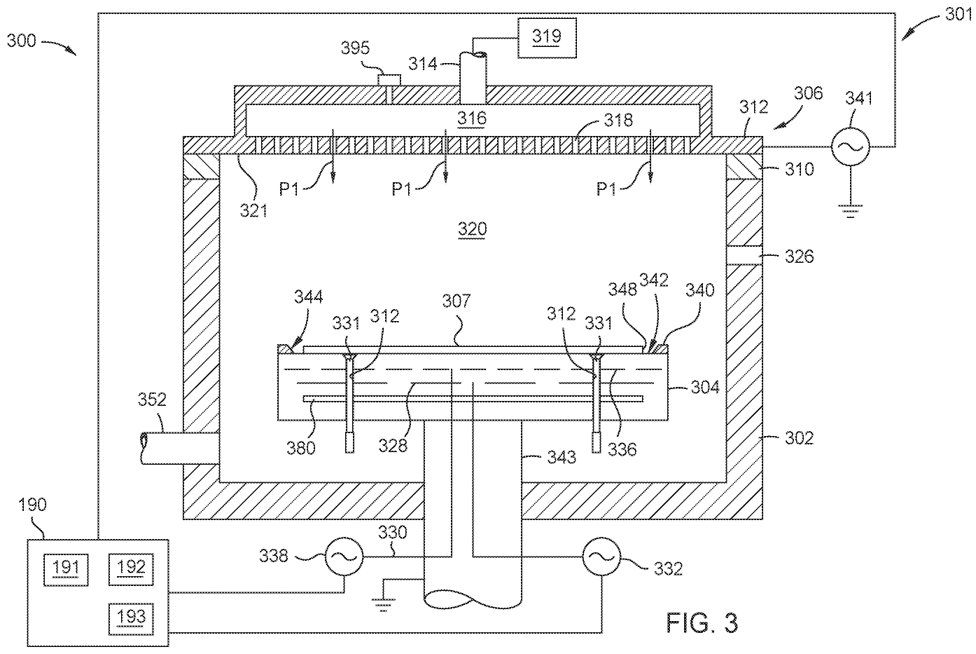

FIG. 3 is a schematic cross-sectional view of a processing chamber 300, according to one or more embodiments. The processing chamber 300 is a chemical vapor deposition (CVD) chamber where substrates are heated. Exemplary processing chambers which may benefit from the implementations described herein include the PRODUCER® series of CVD enabled chambers and/or the PRECISION® series of CVD enabled chambers, available from Applied Materials, Inc., Santa Clara, CA. It is contemplated that other process chambers from other manufacturers may also benefit from the implementations described herein.

The processing chamber 300 includes a chamber body 302, a pedestal 304 disposed within the chamber body 302, and a lid assembly 306 coupled to the chamber body 302 and enclosing the pedestal 304 in a processing volume 320. The lid assembly 306 includes a gas distributor 312. A substrate 307 is provided to the processing volume 320 through an opening 326 (such as a slit valve) formed in the chamber body 302.

An isolator 310, which may be a dielectric material such as a ceramic or metal oxide, for example aluminum oxide and/or aluminum nitride, separates the gas distributor 312 from the chamber body 302. The gas distributor 312 includes openings 318 for admitting process gases into the processing volume 320. The process gases may be supplied to the processing chamber 300 via a conduit 314, and the process gases may enter a gas mixing region 316 prior to flowing through the openings 318. An exhaust 352 is formed in the chamber body 302 at a location below the pedestal 304. The exhaust 352 may be connected to a vacuum pump to remove unreacted species and by-products from the processing chamber 300. The conduit 314 is in fluid communication with one or more gas sources 319 that supply the process gases. The process gases can include one or more of a reactive gas (such as for a deposition operation), an inert gas (such as for a deposition operation), a cleaning gas (such as for a chamber clean operation), and/or a seasoning gas (such as for a seasoning operation). The process gases (shown as P1 in FIG. 3) flow into the processing volume 320 through a ceiling 321 of the processing volume 320. The ceiling 321 can be at least partially defined by a lower surface of the gas distributor 312.

The gas distributor 312 may be coupled to an electric power source 341, such as an RF generator or a DC power source. The DC power source may supply continuous and/or pulsed DC power to the gas distributor 312. The RF generator may supply continuous and/or pulsed RF power to the gas distributor 312. The electric power source 341 is turned on during the operation to supply an electric power to the gas distributor 312 to facilitate formation of a plasma in the processing volume 320.

The pedestal 304 may be formed from a ceramic material, for example a metal oxide or nitride or oxide/nitride mixture such as aluminum, aluminum oxide, aluminum nitride, or an aluminum oxide/nitride mixture. The pedestal 304 is supported by a shaft 343. The pedestal 304 may be grounded. One or more heating elements 328 are embedded in the pedestal 304. In one or more embodiments, the one or more heating elements 328 (one is shown) are one or more resistive heaters. The heating element 328 may be a plate, a perforated plate, a mesh (such as a wire mesh), a wire screen, or any other distributed arrangement. The heating element 328 is coupled to an electric power source 332 via a connection 330. The electric power source 332 may be a power supply that controls the heating element 328. The electric power source 332 supplies electric power (such as an alternating current) to the heating element 328 to generate heat. One or more cooling channels 380 can be formed in the pedestal 304 to cool the substrate 307. The one or more cooling channels 380 receive a cooling fluid to cool the substrate 307.

The pedestal 304 includes an electrode 336 and an electric power source 338 electrically coupled to the electrode 336. The electrode 336 may be a plate, a perforated plate, a mesh (such as a wire mesh), a wire screen, or any other distributed arrangement. The electric power source 338 is configured to supply a chucking voltage and/or RF power to the electrode 136 through the electrode 136. Using the electrode 336, the pedestal 304 is as an electrostatic chuck that chucks the substrate 307 thereto. Using the electrode 336, the electric power source 338 may be utilized to control properties of the plasma formed in the processing volume 320, or to facilitate generation of the plasma within the processing volume 320. For example, the electric power source 341 and the electric power source 338 may be tuned to two different frequencies to promote ionization of multiple species in the processing volume 320. The electric power source 341 and the electric power source 332 may be utilized to generate a capacitively-coupled plasma within the processing volume 320. The present disclosure also contemplates that an inductively-coupled plasma may be used.

The pedestal 304 includes a substrate support face 342 for supporting the substrate 307. The pedestal 304 may include a step 340 having a pocket 344. The step 340 may be an edge ring. The substrate 307 and the step 340 may be concentrically disposed on the substrate support face 342 of the pedestal 304. The step 340 can be integrally formed with the pedestal 304.

The pedestal 304 can be at least a part of a substrate support coupled to the shaft 343. The pedestal 304 can include a single support body, or can include a plurality of bodies, such as a top plate (a support body) having the substrate support face 342 mounted to a base plate, where the base plate is mounted to the shaft 343.

The processing chamber can be used as one or more (such as all) of the first chambers 124 shown in FIG. 1.

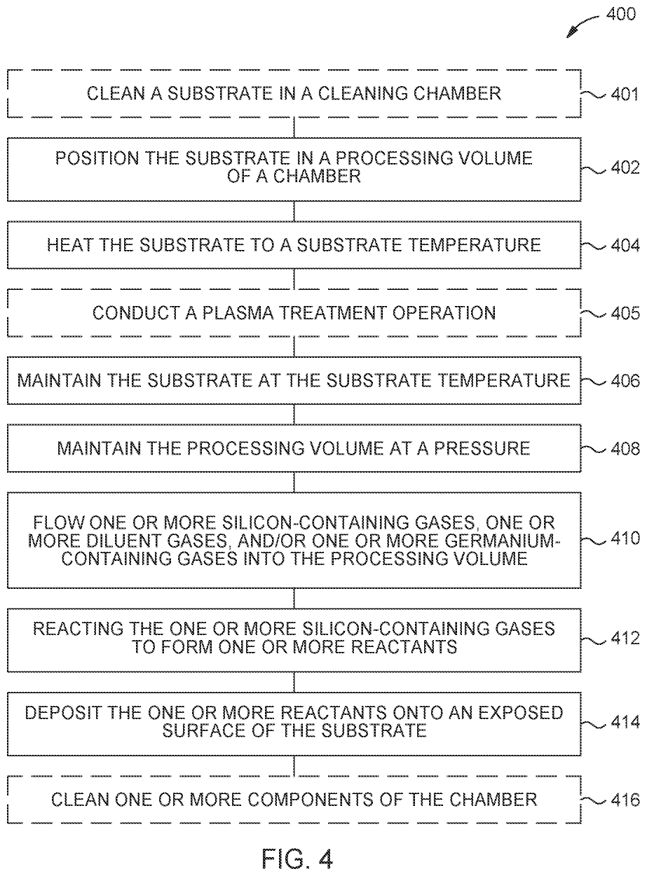

FIG. 4 is a schematic block diagram view of a method 400 of processing substrates, according to one or more embodiments.

Optional operation 401 includes cleaning a substrate in a cleaning chamber. The cleaning includes an etching operation. The etching operation includes one or more of a dry etch (such as dry etching that uses NF₃) and/or a wet etch (such as wet etching that uses dilute hydrofluoric acid (DHF)). The etching operation can include exposing the substrate to plasma (such as from a remote plasma source).

Operation 402 includes positioning the substrate in a processing volume of a chamber. In one or more embodiments, the substrate is positioned in the processing volume of the chamber after transferring the substrate out of the cleaning chamber. The substrate is an Si substrate.

The present disclosure contemplates that one or more of the cleaning chamber and/or the chamber can be seasoned prior to operations 401 and/or 402.

Operation 404 includes heating the substrate to a substrate temperature that is 800 degrees Celsius or less, such as 760 degrees Celsius or less. In one or more embodiments, the substrate temperature is less than 700 degrees Celsius, such as within a range of 450 degrees Celsius to 650 degrees Celsius. In one or more embodiments, the substrate temperature is 600 degrees Celsius or less. In one or more embodiments, the substrate temperature is about 550 degrees Celsius (such as 550 degrees Celsius or within a range of 545 degrees Celsius to 555 degree Celsius). In one or more embodiments, the heating occurs as part of a deposition operation. In one or more embodiments, the heating occurs as part of a bake operation that is conducted before the deposition operation. In one or more embodiments, the bake operation is conducted before the plasma treatment operation of optional operation 405. The bake operation lasts for a bake duration that is about 30 seconds.

Optional operation 405 includes conducting a plasma treatment operation on the substrate. The plasma treatment operation includes forming a plasma in the processing volume, and activating the exposed surface of the substrate using the plasma. The plasma treatment operation includes extinguishing the plasma, and exhausting the processing volume. In one or more embodiments, the plasma is a hydrogen (H₂) plasma. In one or more embodiments, the plasma is a capacitively-coupled plasma, and is generated in-situ in the chamber using a high frequency radio-frequency (HFRF) power source. In one or more embodiments, the plasma is generated by flowing H₂ at a flow rate within a range of 0.1 SCCM to 1,000 SCCM, and applying RF power having a power within a range of 0.1 W to 1,000 W. The plasma treatment operation is conducted at a plasma pressure. In one or more embodiments, the plasma pressure is within a range of 2.5 Torr to 5.0 Torr. In one or more embodiments, the plasma pressure is the same as the pressure used in operation 408 below. The plasma treatment operation lasts for a treatment duration that is about 60 seconds.

Operation 406 includes maintaining the substrate at the substrate temperature.

Operation 408 includes maintaining the processing volume at a pressure that is 300 Torr or less, such as within a range of 0.2 Torr to 300 Torr. In one or more embodiments, the pressure is within a range of 1.0 Torr to 8.0 Torr. In one or more embodiments, the pressure is about 1.0 Torr (such as 1.0 Torr or within a range of 0.9 Torr to 1.1 Torr). In one or more embodiments, the pressure is about 6.0 Torr (such as 6.0 Torr or within a range of 5.8 Torr to 6.2 Torr).

Operation 410 includes flowing one or more silicon-containing gases and one or more diluent gases into the processing volume through a ceiling of the processing volume. In one or more embodiments, operation 410 is conducted after operations 402, 404, 405, 406, and 408 are conducted. The one or more silicon-containing gases includes one or more of SiH₄, Si₂H₆, and/or SiH₂Cl₂. The one or more diluent gases are inert gases and include one or more of nitrogen (N₂), argon (Ar), and/or helium (He). The one or more silicon-containing gases flow at a flow rate within a range of 0.1 SCCM to 1,000 SCCM.

In one or more embodiments, operation 410 includes flowing one or more germanium-containing gases into the processing volume through the ceiling. In one or more embodiments, the one or more germanium-containing gases include one or more of GeH₄ and/or GeF₄. The one or more germanium-containing gases flow at a flow rate within a range of 0.1 SCCM to 1,000 SCCM.

Operation 412 includes reacting the one or more silicon-containing gases to form one or more reactants.

Operation 414 includes depositing the one or more reactants onto an exposed surface of the substrate to form one or more silicon-containing layers on the exposed surface. The one or more silicon-containing layers include one or more Si layers (which can include dopant(s) and/or one or more SiGe layers (which can include dopants. The SiGe layers have a Ge atomic percentage within range of 0.1% to less than 100%. The one or more silicon-containing layers each have a single crystalline structure. In one or more embodiments, the one or more silicon-containing gases react with the exposed surface (at operation 412) of the substrate to form the one or more reactants. In one or more embodiments where the one or more germanium-containing gases are used, the one or more silicon-containing gases react with the one or more germanium-containing gases (at operation 412) to form the one or more reactants.

Optional operation 416 includes cleaning one or more components of the chamber after operation 414, and after the substrate is removed from the chamber. In one or more embodiments, the cleaning includes flowing a plasma having NF₃ into the processing volume. The plasma can be generated in a remote plasma source and supplied to the processing volume.

Operations 406, 408, 410, 412, and/or 414 can be part of a CVD operation. The present disclosure contemplates that one or more operations of the method 400 can be repeated, such as across several substrates and/or to form multiple layers on the same substrate. The method 400 can be used to form one or more layers on a single side of the substrate, or on both sides of the substrate.

The present disclosure contemplates that there may be a vacuum break for the substrate at some point between operation 401 (e.g., a pre-clean operation), and operations 406, 408, 410, 412, 414 (e.g., a CVD operation). In such an embodiment, operations 404, 405 can be used to mitigate effects (such as oxidation) from an ambient environment on the substrate. Operations 404, 405 can be used in relation to other operations.

One or more exemplary implementations can be used in according with the method 400. According to exemplary “Implementation 1” the pressure is about 6.0 Torr (such as 6.0 Torr or within a range of 5.8 Torr to 6.2 Torr), and the substrate temperature is about 550 degrees Celsius (such as 550 degrees Celsius or within a range of 545 degrees Celsius to 555 degree Celsius). In Implementation 1, the one or more silicon-containing gases include Si₂H₆ that flows into the processing volume at a first flow rate within a range of 20 standard cubic centimeters per minute (SCCM) to 200 SCCM (such as about 200 SCCM), and the one or more diluent gases include nitrogen (N₂) that flows into the processing volume at a second flow rate that is about 600 SCCM. In Implementation 1, one or more Si layers are formed on the substrate at a formation rate within a range of 10 nm/minute to 12 nm/minute. Implementation 1 can include a vacuum break less than 4.5 minutes.

According to exemplary “Implementation 2” the pressure is about 1.0 Torr (such as 1.0 Torr or within a range of 0.9 Torr to 1.1 Torr), and the one or more silicon-containing gases include Si₂H₆ that flows into the processing volume at a flow rate within a range of 20 SCCM to 200 SCCM. In Implementation 2, one or more Si layers are formed on the substrate.

According to exemplary “Implementation 3” the pressure is about 6.0 Torr (such as 6.0 Torr or within a range of 5.8 Torr to 6.2 Torr), and the substrate temperature is about 550 degrees Celsius (such as 550 degrees Celsius or within a range of 545 degrees Celsius to 555 degree Celsius). In Implementation 3 the one or more silicon-containing gases include Si₂H₆ that flows into the processing volume at a first flow rate within a range of 20 SCCM to 200 SCCM, and the one or more diluent gases include nitrogen (N₂) that flows into the processing at a second flow rate that is about 600 SCCM. In Implementation 3 the one or more germanium-containing gases are used and include GeH₄ carried in hydrogen (H₂) and flowing into the processing volume at a third flow rate within a range of 10 SCCM to 1,000 SCCM (such as 200 SCCM to 1,000 SCCM). The GeH₄ is about 10% of the third flow rate, and the hydrogen (H₂) is about 90% of the third flow rate. In Implementation 3, one or more SiGe layers are formed on the substrate. The SiGe layers have a Ge atomic percentage within a range of 5% to 60%, and an Si atomic percentage within a range of 40% to 95%. Implementation 3 can include a vacuum break less than 4.0 minutes. In one or more embodiments of Implementation 3, the first flow rate is about 200 SCCM, the third flow rate is about 200 SCCM, and the one or more SiGe layers are formed on the substrate at a formation rate of about 12 nm/minute. In one or more embodiments of Implementation 3, the first flow rate is about 20 SCCM, the third flow rate is about 1,000 SCCM, and the one or more SiGe layers are formed on the substrate at a formation rate of about 41 nm/minute.

According to exemplary “Implementation 4” the pressure is about 1.0 Torr (such as 1.0 Torr or within a range of 0.9 Torr to 1.1 Torr), and the one or more silicon-containing gases include Si₂H₆ that flows into the processing volume at a first flow rate within a range of 20 SCCM to 200 SCCM. In Implementation 4 the one or more germanium-containing gases are used and include GeH₄ carried in hydrogen (H₂) and flowing into the processing volume at a second flow rate within a range of 10 SCCM to 1,000 SCCM (such as 200 SCCM to 1,000 SCCM). The GeH₄ is about 10% of the second flow rate, and the hydrogen (H₂) is about 90% of the second flow rate. The SiGe layers have a Ge atomic percentage within a range of 5% to 60%, and an Si atomic percentage within a range of 40% to 95%.

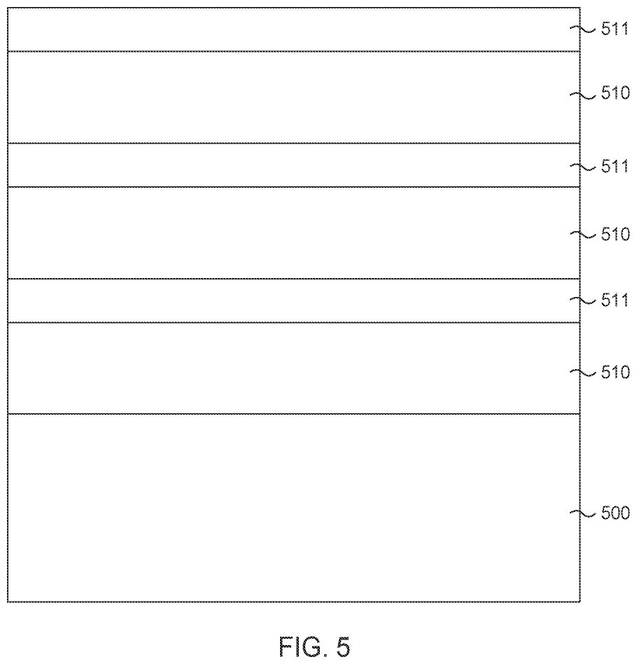

FIG. 5 is a schematic cross-sectional view of a substrate 500 and a plurality of layers 510, 511 formed on the substrate 500, according to one or more embodiments. The layers 510 are SiGe layers and the layers 511 are Si layers. The substrate 500 and each of the layers 510, 511 have single crystalline structures. The layers 510, 511 are formed on the substrate 500 using the method 400, such as by multiple iterations of at least part of the method 400. The substrate 500 with the layers 510, 511 can be used in 3D DRAM applications.

A thickness T1 of the layers 510, 511 has a non-uniformity gradient that is less than 1.0% across the layers 510, 511. Both the substrate 500 and the layers 511, 512 have a haze that is less than 0.5%. Each of the layers 510, 511 has an abruptness that is less than 1.0. Each of the layers 510, 511 has a surface roughness that is less than 0.2 nm.

The single crystalline structure refers to a lattice structure that is completely crystalline and has the same lattice order from end-to-end of the respective material. Each and every grain of the material is aligned in the same direction in the single crystalline structure. The single crystalline structure does not include an amorphous portion.

Benefits of the present disclosure include reduced costs, reduced power consumption, reduced complexity of operations, reduced complexity of components, reduced operation times, enhanced modularity (such as for use with both double-sided deposition operations and single-sided deposition operations), and enhanced throughput. Benefits of the present disclosure also include reduced substrate haze, enhanced substrate-to-substrate uniformity, reduced chamber particle contamination (such as in the deposition chambers), and film non-uniformity that is less than 1.0%.

It is believed that operations and/or parameters described herein facilitate the aforementioned benefits over other operations. As an example, the pressure and the substrate temperature of the method 400 facilitate the benefits. As another example, the operations and the parameters described for exemplary Implementation 1, exemplary Implementation 2, exemplary Implementation 3, and exemplary Implementation 4 facilitate the benefits.

It is contemplated that one or more aspects disclosed herein may be combined. As an example, one or more aspects, features, components, operations, and/or properties of the system 100, the processing chamber 200, the processing chamber 300, the method 400, and/or the substrate 500 and layers 511, 512 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

What is claimed is:

1. A method of processing substrates, comprising:
positioning a substrate in a processing volume of a chamber;
heating the substrate to a substrate temperature that is 800 degrees Celsius or less;
maintaining the processing volume at a pressure within a range of 1.0 Torr to 8.0 Torr.
flowing one or more silicon-containing gases and one or more diluent gases into the processing volume;
reacting the one or more silicon-containing gases to form one or more reactants; and
depositing the one or more reactants onto an exposed surface of the substrate to form one or more silicon-containing layers on the exposed surface, the one or more silicon-containing layers each having a single crystalline structure.

2. The method of claim 1, further comprising, prior to the flowing of the one or more silicon-containing gases:
forming a plasma in the processing volume; and
activating the exposed surface of the substrate using the plasma.

3. The method of claim 2, wherein the substrate is heated to the substrate temperature prior to the forming of the plasma.

4. The method of claim 3, wherein the plasma is a hydrogen (H₂) plasma, and the method further comprises, prior to the flowing of the one or more silicon-containing gases:
extinguishing the plasma; and
exhausting the processing volume.

5. The method of claim 1, wherein the substrate temperature is within a range of 450 degrees Celsius to 650 degrees Celsius.

6. The method of claim 1, wherein the one or more silicon-containing gases react with the exposed surface of the substrate to form the one or more reactants, and the one or more silicon-containing gases and the one or more diluent gases flow into the processing volume through a ceiling of the processing volume.

7. The method of claim 1, wherein the one or more silicon-containing gases comprise one or more of SiH₄, Si₂H₆, or SiH₂Cl₂.

8. The method of claim 7, wherein the pressure is about 6.0 Torr, the substrate temperature is about 550 degrees Celsius, the one or more silicon-containing gases include Si₂H₆ that flows into the processing volume at a first flow rate within a range of 20 SCCM to 200 SCCM, and the one or more diluent gases comprise nitrogen (N₂) that flows into the processing volume at a second flow rate that is about 600 SCCM.

9. The method of claim 7, wherein the pressure is about 1.0 Torr, and the one or more silicon-containing gases include Si₂H₆ that flows into the processing volume at a flow rate within a range of 20 SCCM to 200 SCCM.

10. The method of claim 7, further comprising:
flowing one or more germanium-containing gases into the processing volume through the ceiling, wherein the one or more silicon-containing gases react with the one or more germanium-containing gases to form the one or more reactants.

11. The method of claim 10, wherein the one or more germanium-containing gases comprise one or more of GeH₄ or GeF₄.

12. The method of claim 11, wherein the pressure is about 6.0 Torr, the substrate temperature is about 550 degrees Celsius, the one or more silicon-containing gases include Si₂H₆ that flows into the processing volume at a first flow rate within a range of 20 SCCM to 200 SCCM, the one or more diluent gases comprise nitrogen (N₂) that flows into the processing volume at a second flow rate that is about 600 SCCM, and the one or more germanium-containing gases include GeH₄ carried in hydrogen (H₂) and flowing into the processing volume at a third flow rate within a range of 10 SCCM to 1,000 SCCM.

13. The method of claim 12, wherein the GeH₄ is about 10% of the third flow rate, and the hydrogen (H₂) is about 90% of the third flow rate.

14. The method of claim 11, wherein the pressure is about 1.0 Torr, the one or more silicon-containing gases include Si₂H₆ that flows into the processing volume at a first flow rate within a range of 20 SCCM to 200 SCCM, and the one or more germanium-containing gases include GeH₄ carried in hydrogen (H₂) and flowing into the processing volume at a second flow rate within a range of 10 SCCM to 1,000 SCCM, wherein the GeH₄ is about 10% of the second flow rate, and the hydrogen (H₂) is about 90% of the second flow rate.

15. A non-transitory computer readable medium comprising instructions that, when executed, cause a plurality of operations to be conducted, the plurality of operations comprising:
positioning a substrate in a processing volume of a chamber;
heating the substrate to a substrate temperature that is 800 degrees Celsius or less;
maintaining the processing volume at a pressure within a range of 1.0 Torr to 8.0 Torr.
flowing one or more silicon-containing gases and one or more diluent gases into the processing volume;
reacting the one or more silicon-containing gases to form one or more reactants; and
depositing the one or more reactants onto an exposed surface of the substrate to form one or more silicon-containing layers on the exposed surface, the one or more silicon-containing layers each having a single crystalline structure.

16. The non-transitory computer readable medium of claim 15, wherein the one or more silicon-containing gases comprise one or more of SiH₄, Si₂H₆, or SiH₂Cl₂, the pressure is about 6.0 Torr, the substrate temperature is about 550 degrees Celsius, the one or more silicon-containing gases include Si₂H₆ that flows into the processing volume at a first flow rate within a range of 20 SCCM to 200 SCCM, and the one or more diluent gases comprise nitrogen (N₂) that flows into the processing volume at a second flow rate that is about 600 SCCM.

17. The non-transitory computer readable medium of claim 15, wherein the one or more silicon-containing gases comprise one or more of SiH₄, Si₂H₆, or SiH₂Cl₂, the pressure is about 1.0 Torr, and the one or more silicon-containing gases include Si₂H₆ that flows into the processing volume at a flow rate within a range of 20 SCCM to 200 SCCM.

18. The non-transitory computer readable medium of claim 15, wherein the plurality of operations further comprise:
flowing one or more germanium-containing gases into the processing volume through the ceiling, wherein the one or more silicon-containing gases react with the one or more germanium-containing gases to form the one or more reactants, and wherein the one or more silicon-containing gases comprise one or more of SiH₄, Si₂H₆, or SiH₂Cl₂, the one or more germanium-containing gases comprise one or more of GeH₄ or GeF₄, the pressure is about 6.0 Torr, the substrate temperature is about 550 degrees Celsius, the one or more silicon-containing gases include Si₂H₆ that flows into the processing volume at a first flow rate within a range of 20 SCCM to 200 SCCM, the one or more diluent gases comprise nitrogen (N₂) that flows into the processing volume at a second flow rate that is about 600 SCCM, and the one or more germanium-containing gases include GeH₄ carried in hydrogen (H₂) and flowing into the processing volume at a third flow rate within a range of 10 SCCM to 1,000 SCCM.

19. The non-transitory computer readable medium of claim 15, wherein the plurality of operations further comprise:
flowing one or more germanium-containing gases into the processing volume through the ceiling, wherein the one or more silicon-containing gases react with the one or more germanium-containing gases to form the one or more reactants, and wherein the one or more silicon-containing gases comprise one or more of SiH₄, Si₂H₆, or SiH₂Cl₂, the one or more germanium-containing gases comprise one or more of GeH₄ or GeF₄, the pressure is about 1.0 Torr, the one or more silicon-containing gases include Si₂H₆ that flows into the processing volume at a first flow rate within a range of 20 SCCM to 200 SCCM, and the one or more germanium-containing gases include GeH₄ carried in hydrogen (H₂) and flowing into the processing volume at a second flow rate within a range of 10 SCCM to 1,000 SCCM, wherein the GeH₄ is about 10% of the second flow rate, and the hydrogen (H₂) is about 90% of the second flow rate.

20. A system for processing substrates, comprising:
a chamber, comprising:
one or more sidewalls that at least partially define a processing volume
a substrate support positioned in the processing volume,
one or more heating elements embedded in the substrate support,
a lid at least partially defining a ceiling of the processing volume, the lid comprising one or more gas passages,
a radio-frequency (RF) power source electrically coupled to the chamber; and
a controller comprising instructions that, when executed by a processor, cause a plurality of operations to be conducted, the plurality of operations comprising:
positioning a substrate in the processing volume of the chamber,
heating the substrate to a substrate temperature that is within a range of 545 degrees Celsius to 555 degree Celsius,
forming a plasma in the processing volume,
activating an exposed surface of the substrate using the plasma,
extinguishing the plasma,
exhausting the processing volume,
maintaining the substrate at the substrate temperature,
maintaining the processing volume at a pressure within a range of 5.8 Torr to 6.2 Torr,
flowing one or more silicon-containing gases and one or more diluent gases into the processing volume through the ceiling of the processing volume,
reacting the one or more silicon-containing gases to form one or more reactants, and
depositing the one or more reactants onto the exposed surface of the substrate to form one or more silicon-containing layers on the exposed surface, the one or more silicon-containing layers each having:
a single crystalline structure,
an abruptness that is less than 1.0, and
a surface roughness that is less than 0.2 nm.
